(19) United States
(12) Patent Application Publication
(10) Pub. No.: US 2016/0260729 A1
(43) Pub. Date: Sep. 8, 2016

(54) SEMICONDUCTOR DEVICE, SEMICONDUCTOR MEMORY DEVICE, AND METHOD OF MANUFACTURING SEMICONDUCTOR DEVICE

(71) Applicant: Kabushiki Kaisha Toshiba, Minato-ku (JP)

(72) Inventor: Shoichi MIYAZAKI, Yokkaichi (JP)

(73) Assignee: Kabushiki Kaisha Toshiba, Minato-ku (JP)

(21) Appl. No.: 14/849,697

(22) Filed: Sep. 10, 2015

Related U.S. Application Data
(60) Provisional application No. 62/129,424, filed on Mar. 6, 2015.

(51) Int. Cl. H01L 27/115; H01L 21/762; H01L 29/06; H01L 23/528

(52) U.S. Cl. CPC H01L 27/11565; H01L 27/1157; H01L 23/5283; H01L 21/76229; H01L 29/0649

(57) ABSTRACT

A semiconductor device according to an embodiment described below comprises agate electrode disposed sandwiching a gate insulating film, on an active area. The element isolation insulating film comprises: a first element isolation insulating film having a first width; and a second element isolation insulating film having a second width larger than the first width. The first element isolation insulating film includes in an surface thereof a first element isolation trench having a third width, and the second element isolation insulating film includes in an surface thereof a second element isolation trench having a fourth width larger than the third width. The first element isolation trench has disposed therein a third element isolation insulating film, and the second element isolation trench has disposed therein a fourth element isolation insulating film different from the third element isolation insulating film.

### CROSS REFERENCE TO RELATED APPLICATIONS

This application is based on and claims the benefit of priority from prior U.S. Provisional Patent Application No. 62/129,424, filed on Mar. 6, 2015, the entire contents of which are incorporated herein by reference.

### FIELD

Embodiments described below relate to a semiconductor device, a semiconductor memory device, and a method of manufacturing a semiconductor device.

### BACKGROUND

In recent years, miniaturization and higher levels of integration have been increasingly required in semiconductor devices. For example, in NAND type flash memory, there has been a rising demand not only for miniaturization of a memory region, but also for miniaturization of a peripheral circuit region thereof. However, miniaturization of the peripheral circuit region requires a different method from miniaturization of the memory region, hence it is not easy to effectively achieve miniaturization of the peripheral circuit region while suppressing an increase in the number of steps.

### BRIEF DESCRIPTION OF THE DRAWINGS

FIG. 1 is a block diagram explaining a configuration of a nonvolatile semiconductor memory device according to a first embodiment.

FIG. 2 is a plan view layout diagram showing an overall configuration of a memory cell array 111.

FIG. 3 is a process drawing explaining sidewall transfer technology.

FIG. 4 is a plan view layout diagram showing a configuration of the memory cell array 111.

FIG. 5 is an equivalent circuit diagram of the memory cell array 111.

FIG. 6 is a cross-sectional view of the I-I′ cross-section taken along a word line WL of FIG. 4.

FIG. 7 is a cross-sectional view of the II-II′ cross-section taken along a bit line BL of FIG. 4.

FIG. 8 is a plan view layout diagram of a peripheral circuit region.

FIG. 9 is a cross-sectional view taken along the line A-A′ of FIG. 8.

FIGS. 10 to 19 are process drawings showing manufacturing steps of a semiconductor device of the first embodiment.

FIG. 20 is a cross-sectional view showing a structure of a semiconductor device of a second embodiment.

FIG. 21 is a cross-sectional view showing a structure of a semiconductor device of a third embodiment.

### DETAILED DESCRIPTION

A semiconductor device according to an embodiment described below comprises: an active area where a transistor is provided; an element isolation insulating film that insulates and isolates that active area; and a gate electrode disposed sandwiching a gate insulating film, on the active area. The element isolation insulating film comprises: a first element isolation insulating film having a first width; and a second element isolation insulating film having a second width larger than the first width. The first element isolation insulating film includes in an surface thereof a first element isolation trench having a third width, and the second element isolation insulating film includes in an surface thereof a second element isolation trench having a fourth width larger than the third width. The first element isolation trench has disposed therein a third element isolation insulating film, and the second element isolation trench has disposed therein a fourth element isolation insulating film different from the third element isolation insulating film.

Next, a semiconductor device according to an embodiment will be described with reference to the drawings. A NAND type flash memory will be described below as an example of the semiconductor device, but the present invention is not limited to a NAND type flash memory, and an identical form may be applied also to another semiconductor device having a similar transistor.

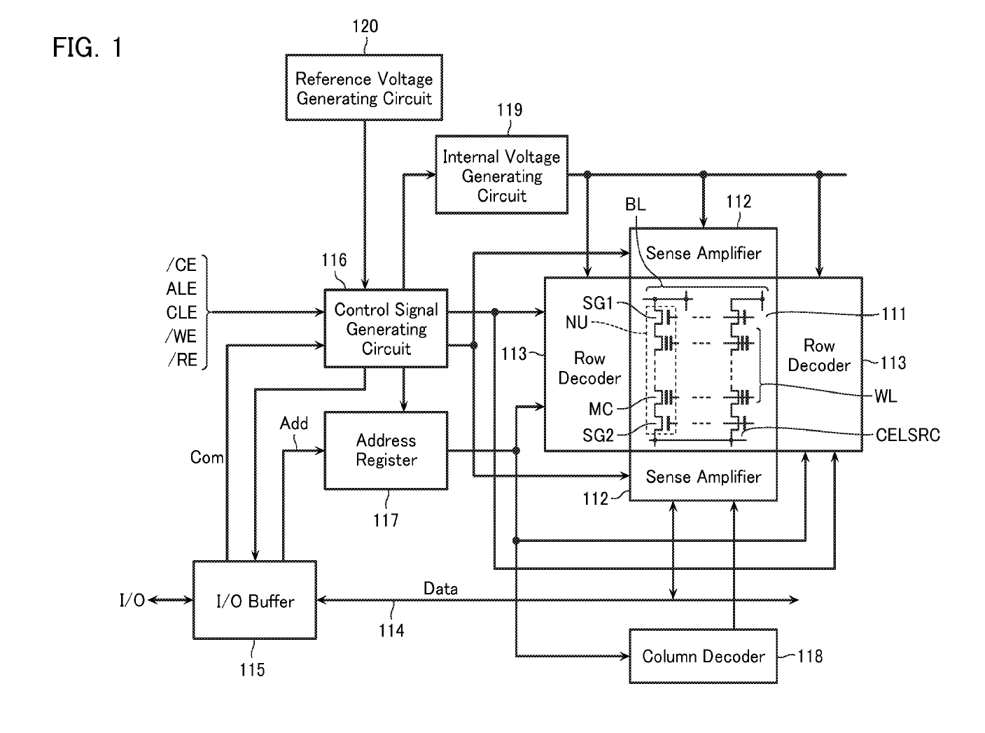

First, a NAND cell type flash memory of an embodiment will be described with reference to FIG. 1.

### First Embodiment

First, a configuration of a nonvolatile semiconductor memory device according to a first embodiment will be described with reference to FIG. 1. FIG. 1 is a block diagram showing the configuration of the nonvolatile semiconductor memory device (NAND type flash memory) according to the first embodiment.

As shown in FIG. 1, the nonvolatile semiconductor memory device according to the first embodiment includes: a memory cell array 111; a sense amplifier 112; a row decoder 113; a data line 114; an I/O buffer 115; a control signal generating circuit 116; an address register 117; a column decoder 118; an internal voltage generating circuit 119; and a reference voltage generating circuit 120. The sense amplifier 112, the row decoder 113, the data line 114, the I/O buffer 115, the control signal generating circuit 116, the address register 117, the column decoder 118, the internal voltage generating circuit 119, and the reference voltage generating circuit 120 are peripheral circuits for operation of the memory cell array 111.

The memory cell array 111 is configured having NAND cell units NU arranged in a matrix therein. Each of the NAND cell units NU includes, for example: a plurality of series-connected electrically rewritable nonvolatile memory cells MC (a memory string) ; and select transistors SG1 and SG2 for respectively connecting both ends of that memory string to a bit line BL and a common source line CELSRC.

Control gates of the memory cells MC in the NAND cell unit NU are connected to different word lines WL. Gates of the select transistors SG1 and SG2 are respectively connected to select gate lines SGD and SGS. A set of NAND cell units NU sharing one word line WL configures a memory block which is a unit of data erase.

Each of the bit lines BL is connected to the sense amplifier 112 shown in FIG. 1. The plurality of memory cells MC commonly connected to one word line WL configures one page or multiple pages.

As shown in FIG. 1, the sense amplifier 112 is disposed in a bit line direction of the memory cell array 111, and is connected to the bit line BL to perform a page unit of data read and serves also as a data latch for storing one page of write data. That is, read and write are performed in a page unit. The sense amplifier 112 is provided with a data cache for temporarily storing input/output data and a column select gate circuit for performing column select (not illustrated).

As shown in FIG. 1, the row decoder 113 is disposed in a word line direction of the memory cell array 111, and selects and drives the word line WL and select gate lines SGD and SGS according to a row address. This row decoder 113 includes a word line driver and a select gate line driver. Moreover, the column decoder 118 that controls the column select gate circuit in the sense amplifier 112 is provided accompanying the sense amplifier 112. The row decoder 113, the column decoder 118, and the sense amplifier 112 configure a read/write circuit for performing data read and write of the memory cell array 111.

Data transfer is performed between an external input/output port I/O and the sense amplifier 112, by the input/output buffer 115 and the data line 114. That is, page data read in the sense amplifier 112 is outputted to the data line 114, and is outputted, via the input/output buffer 115, to the input/output port I/O. Moreover, write data supplied from the input/output port I/O is loaded into the sense amplifier 112 via the input/output buffer 115.

Address data Add supplied from the input/output port I/O is supplied to the row decoder 113 and the column decoder 118 via the address register 117. Command data Com supplied from the input/output port I/O is decoded to be set in the control signal generating circuit 116.

Each of external control signals, that is, a chip enable signal/CE, an address latch enable signal ALE, a command latch enable signal CLE, a write enable signal/WE, and a read enable signal/RE are supplied to the control signal generating circuit 116. The control signal generating circuit 116, in addition to performing operation control of memory operations in general, controls the internal voltage generating circuit 119 to generate various kinds of internal voltages required in data read, write, and erase, based on the command Com and the external control signal. Moreover, the control signal generating circuit 116 is applied with a reference voltage from the reference voltage generating circuit 120. The control signal generating circuit 116 performs write from a selected memory cell M on a source line SL side and controls a read operation.

### (Plan View Layout Diagram)

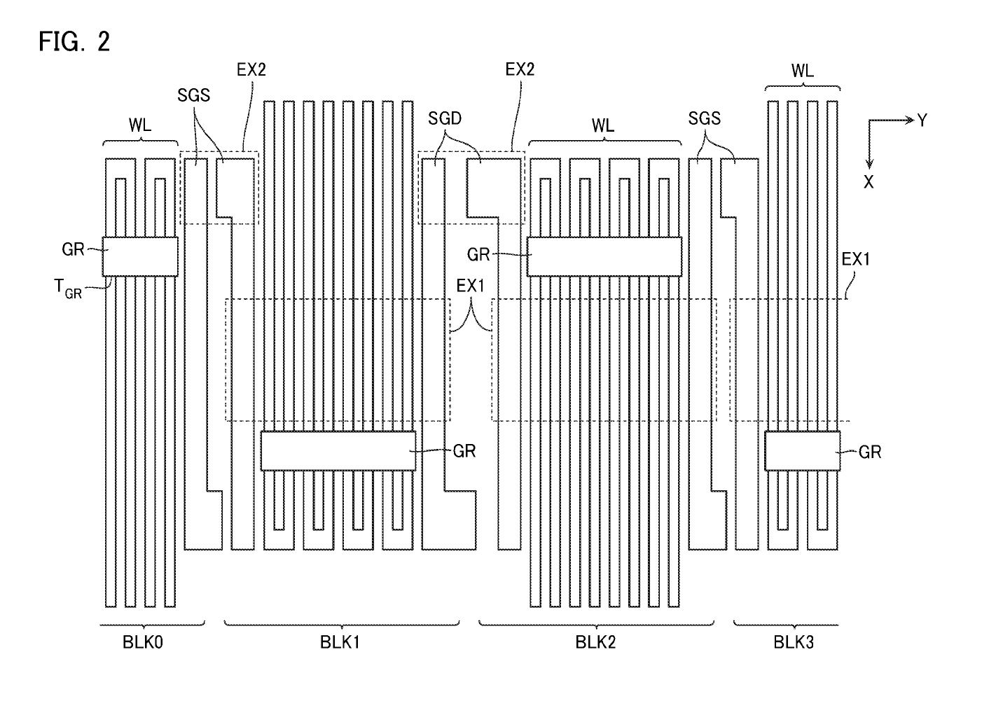

FIG. 2 is a plan view layout diagram showing an overall configuration of the memory cell array 111. FIG. 1 is a plan view showing wiring lines of portions of word lines WL and select gate lines SGS and SGD, and omits illustration of wiring lines in different layers.

As shown in FIG. 2, the NAND type flash memory of the embodiment is configured by a plurality of memory blocks BLKi (i=0, 1, 2, . . . ) arranged in a Y direction. Formed in a region EX1 shown by a dotted rectangle in FIG. 2 is a memory cell array of the memory block BLKi (i=0, 1, 2, . . . ). The configuration of the memory cell array will be mentioned later.

One memory block BLKi is a set of memory cells configuring a minimum unit of a data erase operation, and details of structure of the memory block BLKi will be mentioned later. In FIG. 2, although omitted from illustration, bit lines BL are arranged with a certain pitch in an X direction and having the Y direction as their longer direction, on the region EX1.

In each of the memory blocks BLKi, a plurality of the word lines WL are arranged with a certain pitch in the Y direction and having the X direction as their longer direction. In order to obtain a line width exceeding a resolution limit of lithography, wiring lines of the word lines WL or bit lines BL, and so on, are formed employing so-called sidewall transfer technology.

### (Sidewall Transfer Technology)

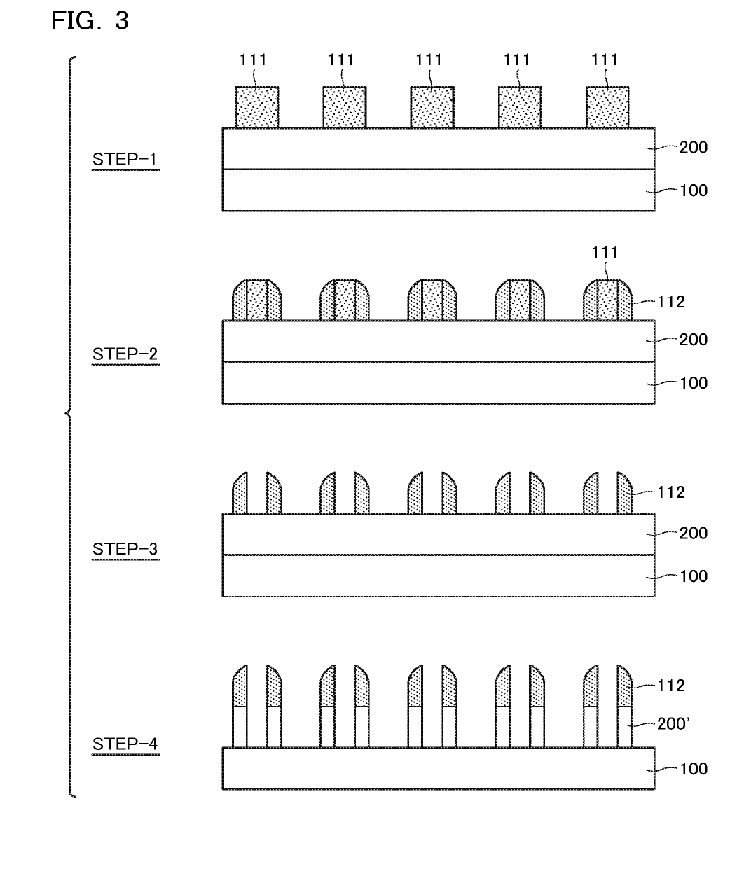

Sidewall transfer technology will be simply described with reference to FIG. 3.

First, a wiring line material 200 for forming a wiring line layer acting as the word line WL is deposited on a semiconductor substrate 100, and a hard mask 111 is formed on this wiring line material 200. As shown in STEP-1 of FIG. 3, this hard mask 111 is patterned to a desired wiring line pattern by photolithography and etching using a resist not illustrated.

Next, as shown in STEP-2, so-called slimming processing is performed by isotropic etching to thin a width of the hard mask 111. Then, a thin film acting as a sidewall transfer process-dedicated sidewall film is deposited on an entire surface including a sidewall of this hard mask 111. A part deposited on an upper surface of the hard mask 111 and an upper surface of the material film 200 of this thin film is removed by etching using anisotropic etching, or the like, and a sidewall process-dedicated sidewall film 112 is formed only on the sidewall of the hard mask 111.

The hard mask 111 may be configured from, for example, a BSG film. The sidewall film 112 is formed by a material having a high selection ratio with respect to the hard mask 111, and in the case that, for example, the hard mask 111 is configured from a BSG film, may be formed adopting, for example, a silicon nitride film as its material.

Next, as shown in STEP-3, the hard mask 111 is removed by etching by wet etching employing an alkaline-system solution, and only the sidewall film 112 having a high selection ratio with respect to the hard mask 111, is left. Then, as shown in STEP-4, the wiring line material 200 is etched to form a wiring line layer 200′ by anisotropic etching using this sidewall film 112 as a mask. The sidewall film 112 is formed so as to have a closed loop shape covering an outer periphery of the patterned hard mask 111, hence the wiring line layer 200′ also is formed in a closed loop shape along this sidewall film 112. The wiring line layer 200′ formed in the closed loop shape is cut at any (some, a certain) position and utilized as various kinds of wiring lines. In the case of a NAND type flash memory, the closed loop is cut at any two places of the closed loop shape, and two open loop state wiring lines are formed from one closed loop shaped wiring line. As a result, a line-and-space pattern of a wiring line width F and wiring line pitch 2F (spacing F) can be formed from a hard mask that has been formed with a wiring line pitch 4F by lithography of a resolution limit 2F.

Note that it is also possible that, after the hard mask 111 has been removed, a sidewall film is further formed on the sidewall of the sidewall film 112 and the sidewall film 112 is removed to leave said sidewall film, whereby further miniaturization is achieved.

### (Cutting of Closed Loop State Wiring Line)

Description of the present embodiment will be continued returning to FIG. 2.

As mentioned above, in the case that sidewall transfer technology is employed, each of the word lines WL is configured as a closed loop state wiring line along a sidewall of a sacrifice film eventually removed by etching. Explaining this with reference to FIG. 2, the hard mask 111 is formed in the region EX1 and a sidewall film is formed on a sidewall of this hard mask 111, after which the hard mask 111 is removed to perform etching using said side wall film as a mask, whereby the word line WL is formed as a closed loop state wiring line.

Furthermore, this closed loop state wiring line is cut in two places by, for example, an insulating isolation film GR shown in FIG. 2, whereby multiple word lines extending in the X direction are formed. For example, the word line WL in memory block BLK1 of FIG. 2 is formed in a closed loop shape using sidewall transfer technology but is cut at the insulating isolation film GR and further undergoes a loop cut at a portion not illustrated, whereby the word line WL is configured as striped wiring lines aligned in the X direction. Such an insulating isolation film GR may be formed by forming an insulating isolation trench T_{GR} that divides a region of conductive layers formed in a loop state and implanting that insulating isolation trench T_{GR} with an insulating film such as a silicon oxide film.

### (Structure of Memory Cell Array)

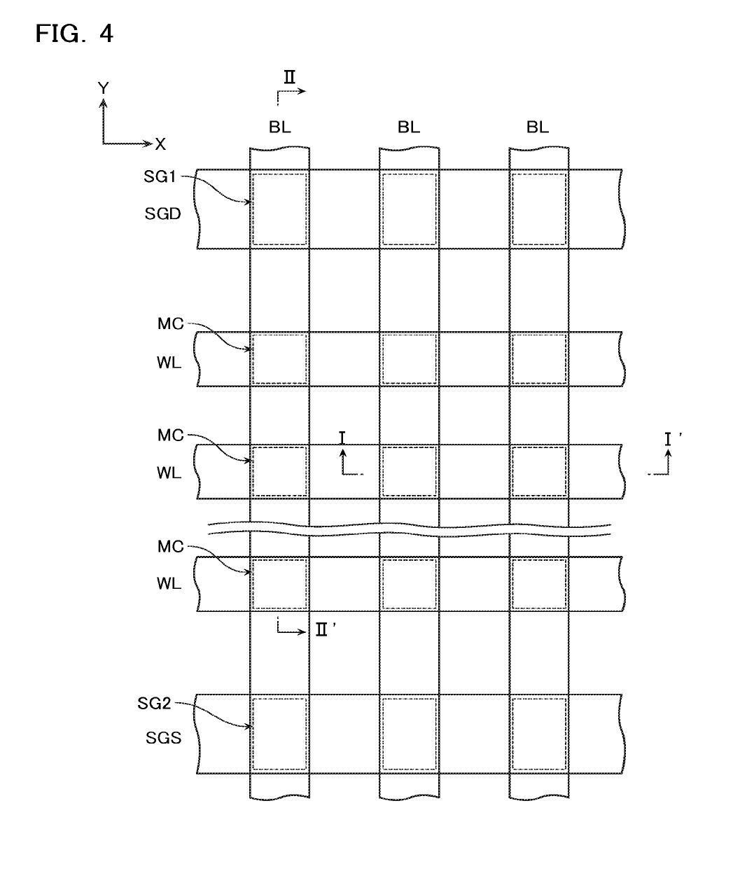

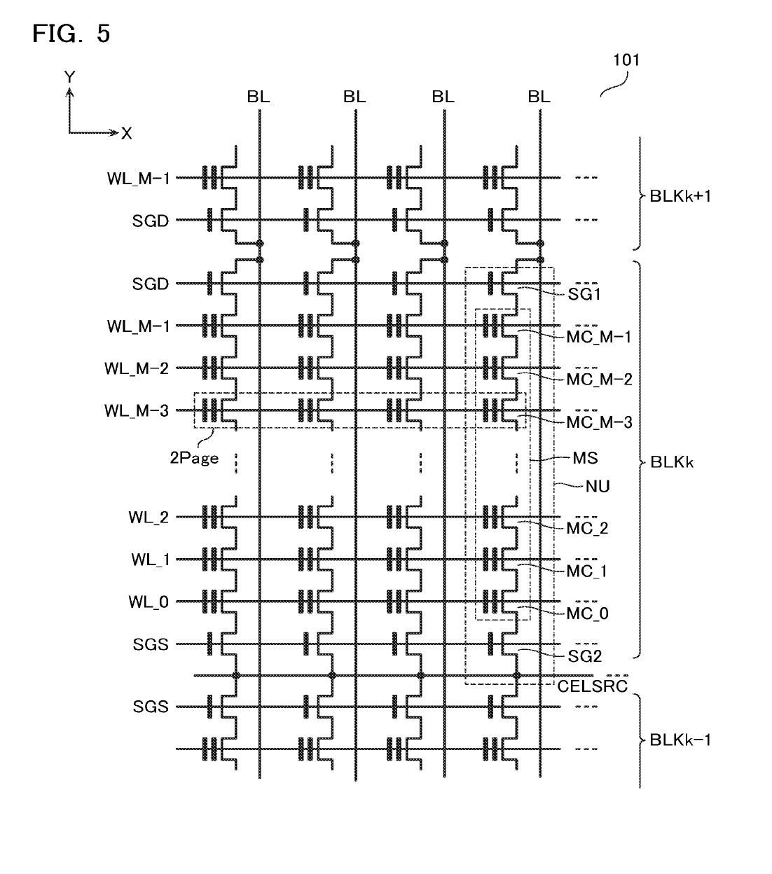

Next, a structure of the memory cell array of the NAND type flash memory according to the embodiment will be described with reference to the layout diagram of FIG. 4 and the equivalent circuit diagram of FIG. 5.

Word lines WL extending in an X direction and bit lines BL extending in a Y direction are arranged intersecting each other, and a memory cell MC is formed at each of intersections of these word lines WL and bit lines BL. As shown in FIG. 5, the bit lines BL are arranged so as to straddle a plurality of memory blocks BLKi (i=0, 1, 2, . . . ). Although illustration thereof is omitted, the bit line BL is connected to a sense amplifier circuit that detects and amplifies a potential of the bit line BL.

A plurality (for example, M) of the memory cells MC (MC_0 to MC_M−1) aligned in the Y direction are connected in series via source/drain diffusion layers to configure one memory string MS. Sometimes, the memory cells at both ends of one memory string MS are configured as dummy cells not employed in data storage. Note that one memory string MS and select transistors SG1 and SG2 at both ends of that memory string MS configure one NAND cell unit NU. Moreover, a plurality of the NAND cell units NU aligned in the X direction are commonly connected by identical word lines WL and select gate lines SGS and SGD, and configure one memory block BLK. Although illustration thereof is omitted, the memory block BLK is formed in one well, whereby a minimum unit of a data erase operation is formed.

One end (a first end portion) of the memory string MS is connected to the bit line BL via the drain side select gate transistor SG1. The bit line BL and the drain side select gate transistor SG1 are connected via a contact not illustrated.

Moreover, the other end (a second end portion) of the memory string MS is connected to a source line CELSRC via the source side select gate transistor SG2. The source line CELSRC and the source side select gate transistor SG2 are connected via a contact not illustrated.

A gate of the drain side select gate transistor SG1 is connected to the drain side select gate line SGD arranged in parallel to the word line WL. Moreover, a gate of the source side select gate transistor SG2 is connected to the source side select gate line SGS arranged in parallel to the word line WL.

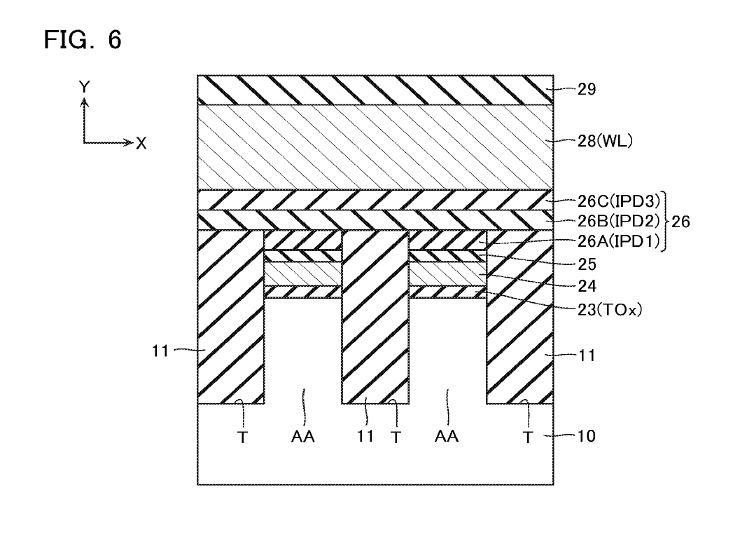

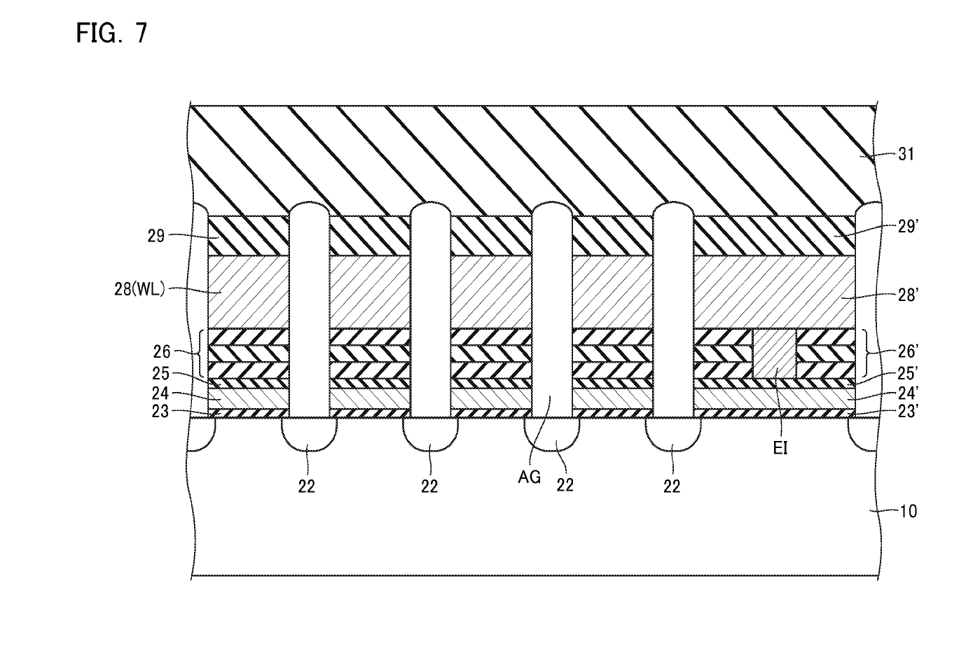

FIG. 6 is a cross-sectional view of the I-I′ cross-section taken along the word line WL of FIG. 4; and FIG. 7 is a cross-sectional view of the II-II′ cross-section taken similarly along the bit line BL of FIG. 4. As shown in FIG. 6, formed in a cell array region above the silicon substrate 100 shown in FIG. 2, via an n type well not illustrated, is a p type well 10. Formed in this p type well 10, with a certain pitch in the X direction and having the Y direction as their longer direction, are trenches T. Moreover, implanted in this trench T is an element isolation insulating film 11. The element isolation insulating film 11 is formed from, for example, silicon oxide (SiO2).

The silicon substrate 100 (p type well 10) sandwiched by the element isolation insulating films 11 constitutes an active area AA where the memory string (memory cell) is formed. That is, an surface of the silicon substrate 100 is electrically isolated into a plurality of active areas AA by the element isolation insulating film 11. The active areas AA are formed with a certain spacing in the X direction and extending having the Y direction as their longer direction, similarly to the element isolation insulating films 11.

As shown in FIG. 7, the plurality of memory cells MC forming the NAND cell unit NU comprise: a plurality of source/drain diffusion layers 22 disposed in an surface of the p type well 10 (active area AA); a tunnel insulating film 23 disposed on a channel region between these source/drain diffusion layers 22; and a floating gate 24 disposed on the tunnel insulating film 23. A film thickness of the tunnel insulating film 23 may be set to about 6 nm, for example. Moreover, a film thickness of the floating gate 24 may be set to about 10 to 25 nm, for example. Note that it is also possible for the source/drain diffusion layer 22 to be omitted when a distance between the plurality of fellow memory cells MC is short. This is because due to a so-called fringe effect, a conduction path penetrating the channel region of the plurality of memory cells MC can be generated, even without the source/drain diffusion layer 22.

Furthermore, this memory cell MC comprises a charge accumulation film 25 disposed on the floating gate 24. This charge accumulation film 25 has a function of accumulating a charge injected into the floating gate 24 via the tunnel insulating film 23 by a write operation, and is formed by, for example, silicon nitride (SiN). A threshold voltage of the memory cell MC changes by an amount of charge accumulated in this charge accumulation film 25 and the floating gate 24, and data stored in the memory cell MC is determined based on this threshold voltage.

A film thickness of the charge accumulation film 25 may be set to about 2 nm, for example. Existence of the charge accumulation film 25 makes it possible for aspect ratio of the floating gate 24 to be reduced.

Formed on this charge accumulation film 25 is a block insulating film 26. This block insulating film 26 is, for example, configured by: a first insulating film 26A configured from hafnium oxide (HfOx); a second insulating film 26B configured from silicon oxide (SiO2); and a third insulating film 26C configured from hafnium oxide (HfOx). Deposited on this block insulating film 26 is a conductive film 28 acting as the word line WL. Film thicknesses of the first insulating film 26A, the second insulating film 26B, and the third insulating film 26C may each be set to about 5 nm, for example. In this example illustrated in FIG. 7, the first insulating film 26A, by having a CMP method executed thereon, has its upper surface substantially matched in height in a Z direction to an upper surface of the element isolation insulating film 11, and is provided only between the element isolation insulating films 11. Moreover, the second insulating film 26B and the third insulating film 26C are formed in stripes having an X axis direction as their longer direction similarly to the word line WL, on flattened upper surfaces of the first insulating film 26A and the element isolation insulating film 11. Note that the block insulating film 26 has a three-layer structure in the illustrated example, but the present invention is not limited to this configuration, and it is also possible for the block insulating film 26 to be configured as a single-layer structure in which the block insulating film 26 is formed by a single material. Moreover, an interface layer may exist between the charge accumulation film 25 and the block insulating film 26.

The conductive film 28 is formed by a metal such as tungsten (W). A stacked structure of a polycrystalline silicon film 13a and a metal silicide may be adopted in place of a metal film.

Deposited in a layer above this conductive film 28 is a cap insulating film 29. This cap insulating film 29 is configured from, for example, a silicon nitride film (SiN), and is formed so as to have a film thickness of about 20 nm, for example.

As shown in FIG. 7, an inter-layer insulating film 31 is formed in a layer above this cap insulating film 29, so as to cover a gate electrode structure of the memory cell MC. However, this inter-layer insulating film 31 is formed by a material having poor implanting properties, for example, a plasma silane film (P—SiH4). Therefore, a gap between gate electrodes aligned in the Y direction is not implanted by the inter-layer insulating film 31, and as shown in FIG. 7, an air gap AG remains. The fact that the air gap AG remains results in inter-cell interference between adjacent memory cells being suppressed. Note that it is also possible for the gap between gate electrode structures of the memory cell to be implanted by the inter-layer insulating film 31, without forming the air gap AG.

A substantially identical gate electrode structure to that of the memory cell MC is formed also in a region of the select gate transistors SG1 and SG2. That is, the gate electrode of the select gate transistors SG1 and SG2 is configured from a stacked structure of a tunnel insulating film 23′, a floating gate 24′, a charge accumulation film 25′, an inter-gate insulating film 26′, a conductive film 28′, and a cap insulating film 29′, similar to that of the memory cell MC. The tunnel insulating film 23′, the floating gate 24′, the charge accumulation film 25′, the inter-gate insulating film 26′, and the conductive film 28′ have widths in a cross direction which are larger than, but film thicknesses which are substantially identical to, and are formed in steps which are identical to those of, respectively, the tunnel insulating film 23, the floating gate 24, the charge accumulation film 25, the inter-gate insulating film 26, and the conductive film 28 of the memory cell MC. However, in the select gate transistors SG1 and SG2, the inter-gate insulating film 26′ is removed by etching, whereby an opening EI is formed and the floating gate 24′ and the conductive film 28′ which is the control gate are configured to be in a short-circuited state via this opening EI.

The memory cell shown in FIGS. 6 and 7 has a so-called flat cell structure in which an upper surface of the element isolation insulating film 11 is at a higher position than an surface of the floating gate 24. However, this is merely one example, and it is possible to apply the technology of this embodiment also to a structure in which the upper surface of the element isolation insulating film 11 is at a lower position than the surface of the floating gate 24 (also called a rocket cell structure).

### (Structure of Peripheral Circuit Region)

Next, a structure of a peripheral circuit region will be described. As previously mentioned, formed in the peripheral circuit region are, for example, the sense amplifier 112, the row decoder 113, the I/O buffer 115, the control signal generating circuit 116, the address register 117, the column decoder 118, the internal voltage generating circuit 119, or the reference voltage generating circuit 120, and so on, shown in FIG. 1.

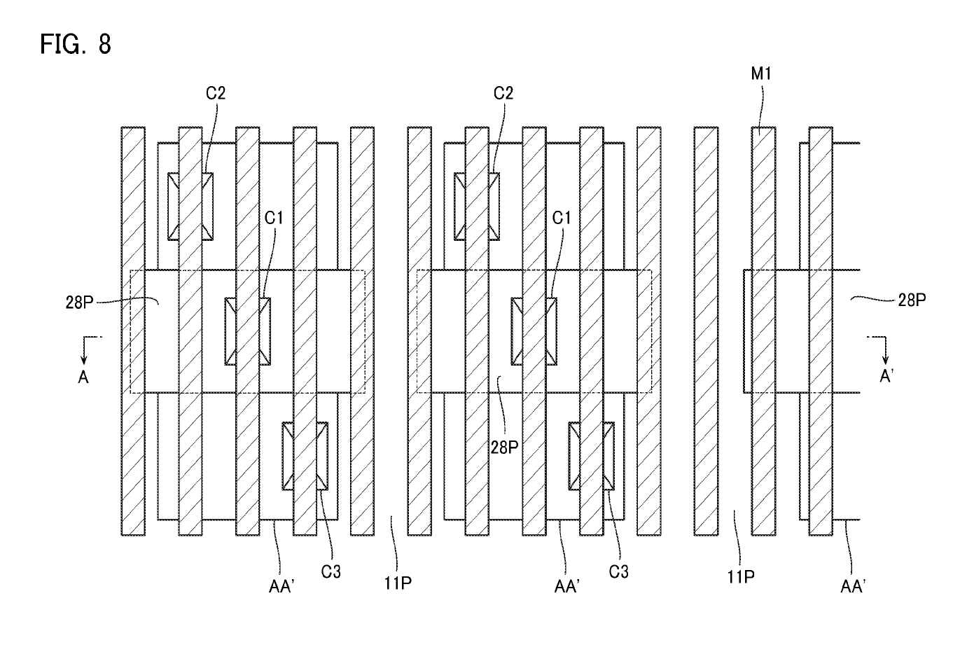

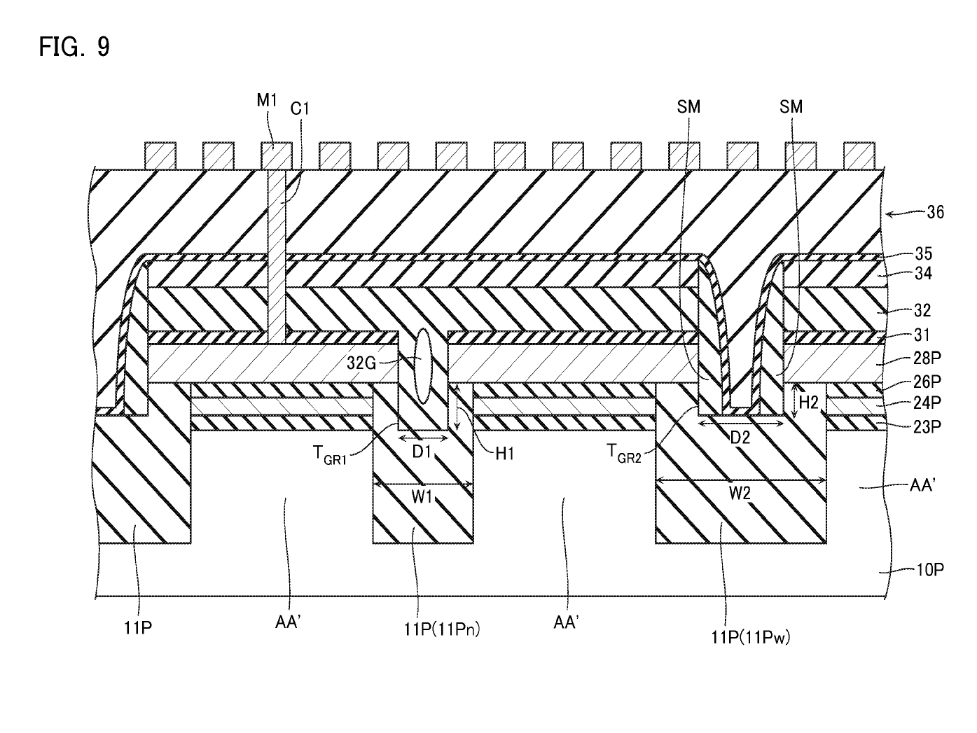

FIG. 8 is a plan view layout diagram showing a schematic structure of a region where a transistor configuring a peripheral circuit (peripheral transistor) is formed. Moreover, FIG. 9 is a cross-sectional view taken along the line A-A′ of FIG. 8.

As shown in FIG. 8, formed in the peripheral circuit region is an active area AA′ for everyone transistor. The active area AA′ is formed by insulating and isolating a p type well 10P by an element isolation insulating film 11P, similarly to the active area AA in the memory cell array 111. Note that the element isolation insulating film 11P includes a narrow-width element isolation insulating film 11Pn (width W1) and a broad-width element isolation insulating film 11Pw (width W2 (>W1)).

A gate electrode 28P is formed so as to straddle each of a plurality of these active areas AA′. This gate electrode 28P functions as a gate electrode of the transistor formed in one active area AA′, and may be formed from, for example, n type or p type polysilicon.

As shown in FIG. 9, the gate electrode 28P is formed on the active area AA′ via a gate insulating film 23P, a floating gate 24P, and an inter-gate insulating film 26P. These gate insulating film 23P, floating gate 24P, and inter-gate insulating film 26P are formed by identical steps, employing identical materials, and hence have substantially identical film thicknesses to those of, respectively, the gate insulating film 23, the floating gate 24, and the inter-gate insulating film 26 formed in the memory cell array 111. Note that the inter-gate insulating film 26P includes an opening at a position not illustrated in FIG. 9, and that the floating gate 24P and the gate electrode 28P are short-circuited via this opening.

Along with demands for miniaturization of the peripheral circuit region, it is being required that a spacing between these gate electrodes 28P is further reduced. In the present embodiment, an element isolation trench T_{GR1} is formed in part of an surface of the element isolation insulating film 11P positioned between the active areas AA′. The gate electrode 28P is insulated and isolated by an element isolation insulating film 32 implanted in this element isolation trench T. This element isolation trench T_{GR1} is formed simultaneously to, and by an identical step to that of the element isolation trench T_{GR} for cutting the loop state word line WL formed by the previously mentioned sidewall transfer technology. The element isolation insulating film 32 is deposited inside the element isolation trench T_{GR1} and above an inter-layer insulating film 31 formed on an upper surface of the gate electrode 28P. This element isolation insulating film 32 is implanted and formed inside the element isolation trench T_{GR1} by an identical material, and in an identical step, to that of an insulating film implanted in the element isolation trench T_{GR} acting as a loop cut insulating film.

As shown in FIG. 9, the element isolation insulating film 32 is formed inside the element isolation trench T_{GR1} and above the gate electrode 28P, so as to have a substantially T shape in the cross-sectional view. Due to the existence of such an element isolation insulating film 32, two gate electrodes 28P facing each other sandwiching the element isolation insulating film 11P are reliably insulated and isolated by a width of the element isolation trench T_{GR1}. In other words, positions of end portions of two gate electrodes 28P facing each other via the element isolation insulating film 32 substantially match a position of aside surface of the element isolation trench T_{GR1}.

Note that the element isolation insulating film 32 may be formed adopting a silane film (SiH4) as its material, for example. In the case of the element isolation insulating film 32 being formed by a silane film, because implanting characteristics of the silane film are low, the inside of the element isolation trench T_{GR1} is not completely filled by the silane film, and an air gap 32G of the kind shown in FIG. 9 can be formed.

Furthermore, formed on an upper surface of this element isolation insulating film 32 is an inter-layer insulating film 34 formed by, for example, a dTEOS film (a TEOS film generated by a plasma CVD method). Deposited above the inter-layer insulating film 34, via a later-to-be-described liner film 35 (for example, a silicon nitride film), is an inter-layer insulating film 36. Disposed above the inter-layer insulating film 36 is a metal wiring line M1. The metal wiring line M1 is a metal wiring line for connecting to an external circuit the gate electrode 28P or a source/drain diffusion layer of a transistor not illustrated. For example, as shown in FIG. 9, the metal wiring line M1 and the gate electrode 28P may be electrically connected to each other by a contact C1 formed by penetrating the inter-layer insulating film 36, and so on.

Note that in the semiconductor device of this first embodiment, it is only in the surface of the narrow-width element isolation insulating film 11P (11Pn) that the element isolation trench T_{GR1} is formed and has its inside implanted with the element isolation insulating film 32. On the other hand, in the element isolation insulating film 11P (11Pw) of broader width than the element isolation insulating film 11Pn, an element isolation trench T_{GR2} of broader width than the element isolation trench T_{GR1} is formed. A width D2 of this element isolation trench T_{GR2} is larger than a width Dl of the element isolation trench T_{GR1}. Moreover, formed inside the element isolation trench T_{GR2} is an element isolation insulating film different from the element isolation insulating film 32, for example, a sidewall film SM, the liner film 35, and the inter-layer insulating film 36. The sidewall film SM is formed on a sidewall of the element isolation trench T_{GR2}, and is configured from, for example, a silicon oxide film. The liner film 35 is formed on a sidewall of this sidewall film SM and on an upper surface of the inter-layer insulating film 34. The liner film 35 may be configured from, for example, a silicon nitride film (SiN).

### (Method of Manufacturing)

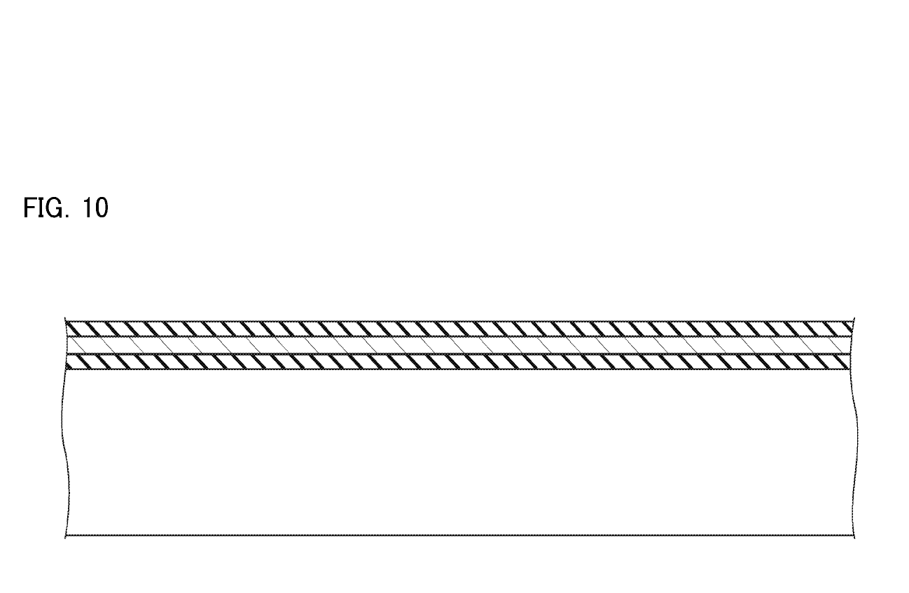

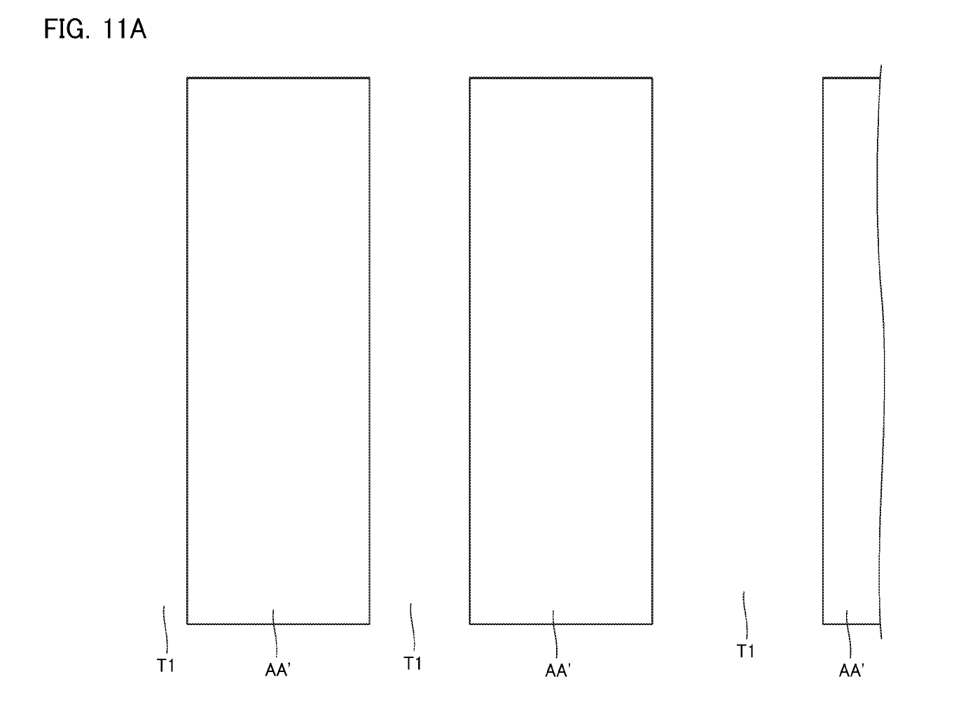

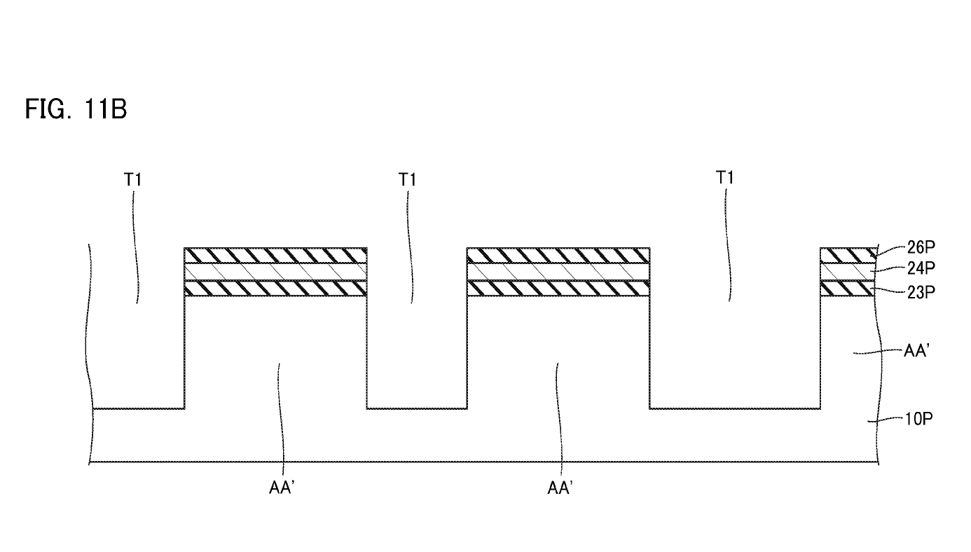

Next, a method of manufacturing a semiconductor device of the first embodiment will be described with reference to the process drawings of FIGS. 10 to 19. A method of manufacturing a portion of the memory cell array 111 is well-known, hence a description thereof will be omitted herein, and a method of manufacturing the peripheral circuit region will be described. Note that FIGS. 11A, 14A, and 16A are plan views corresponding to a portion of FIG. 8 explaining the method of manufacturing of the peripheral circuit region, and the other drawings are cross-sectional views corresponding to a portion of FIG. 9 explaining the method of manufacturing of the peripheral circuit region.

First, as shown in FIG. 10, a silicon oxide film, a polysilicon film, and a silicon oxide film acting as materials of the gate insulating film 23P, the floating gate 24P, and the inter-gate insulating film 26P are deposited sequentially on an entire surface of an upper surface of the p type well 10P of the peripheral circuit region.

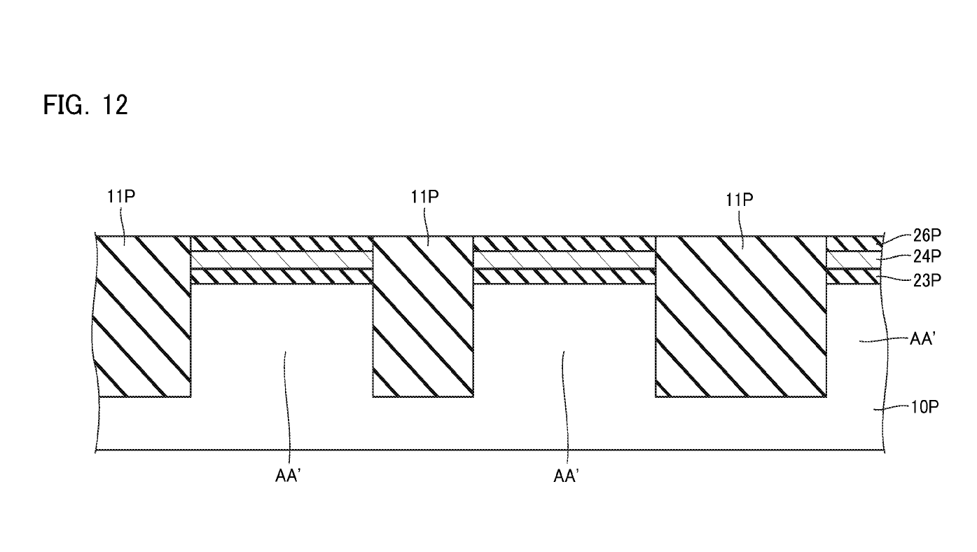

Then, as shown in FIGS. 11P, and 11B, these gate insulating film 23P, floating gate 24P, and inter-gate insulating film 26P are penetrated and a trench T1 reaching the p type well 10P is formed, and then, as shown in FIG. 12, a CVD method or the like is employed to deposit in this trench T1 a silicon oxide film acting as the element isolation insulating film 11P.

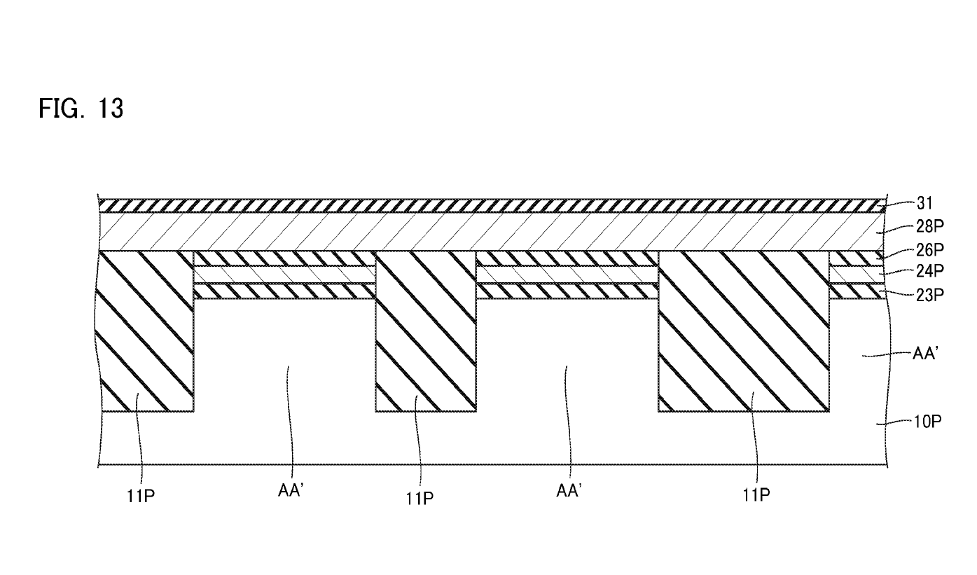

Next, as shown in FIG. 13, a polysilicon film and a silicon oxide film acting as the gate electrode 28P and the inter-layer insulating film 31 are deposited sequentially on upper surfaces of the element isolation insulating film 11P and the inter-gate insulating film 26P.

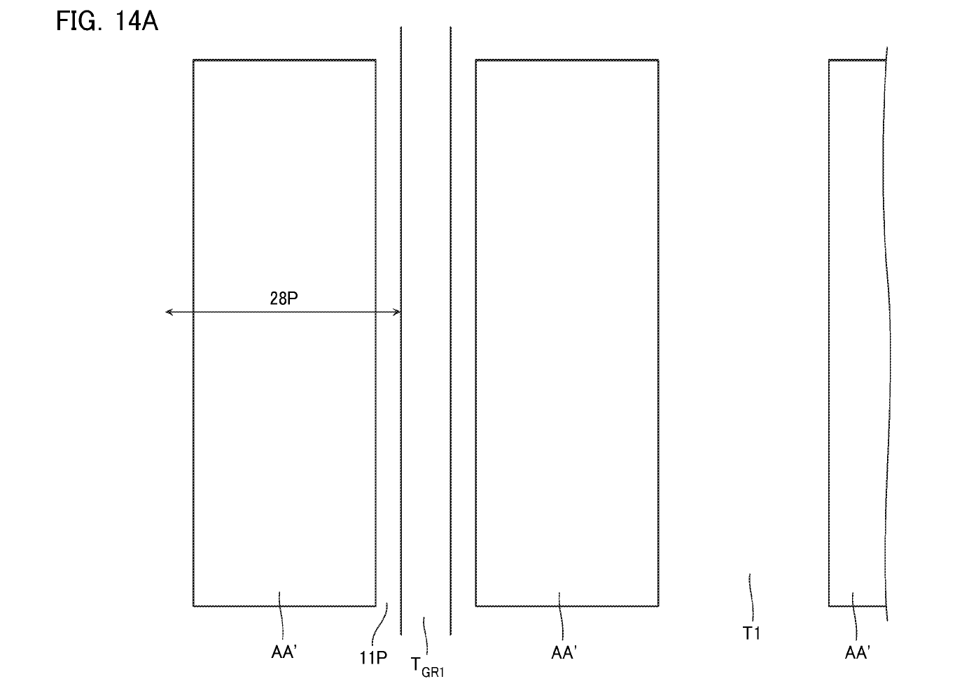

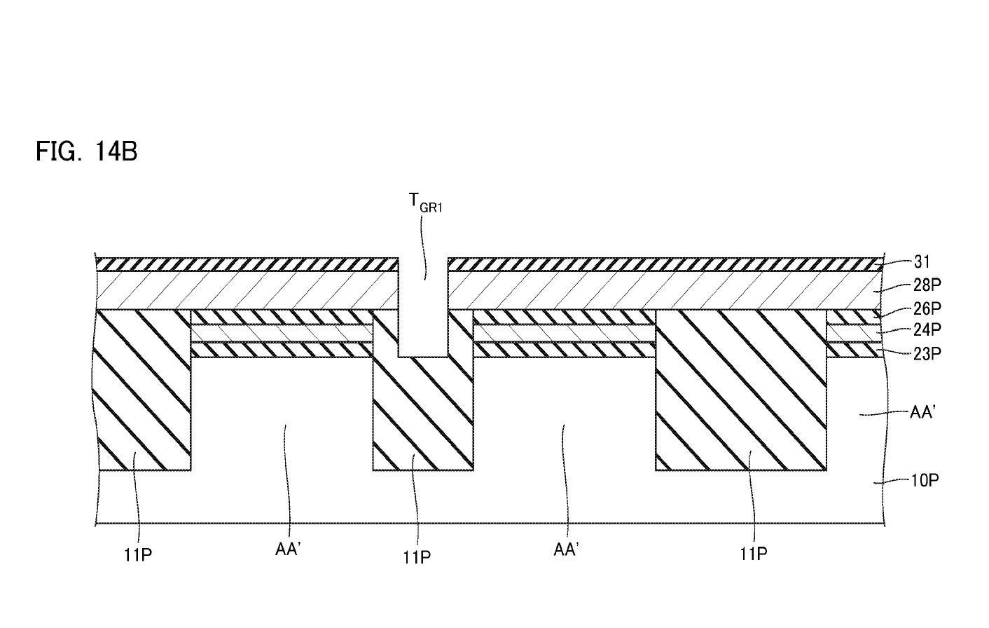

Next, as shown in FIGS. 14A and 14B, the element isolation trench T_{GR1} is formed along a longer direction of the narrow-width element isolation insulating film 11P. As previously mentioned, this element isolation trench T_{GR1} is formed simultaneously to the element isolation trench T_{GR} for cutting the conductive layer formed in a loop shape by sidewall transfer technology. This element isolation trench T_{GR1} causes the gate electrode 28P of two active areas AA′ facing each other sandwiching the narrow-width element isolation insulating film 11P to be cut.

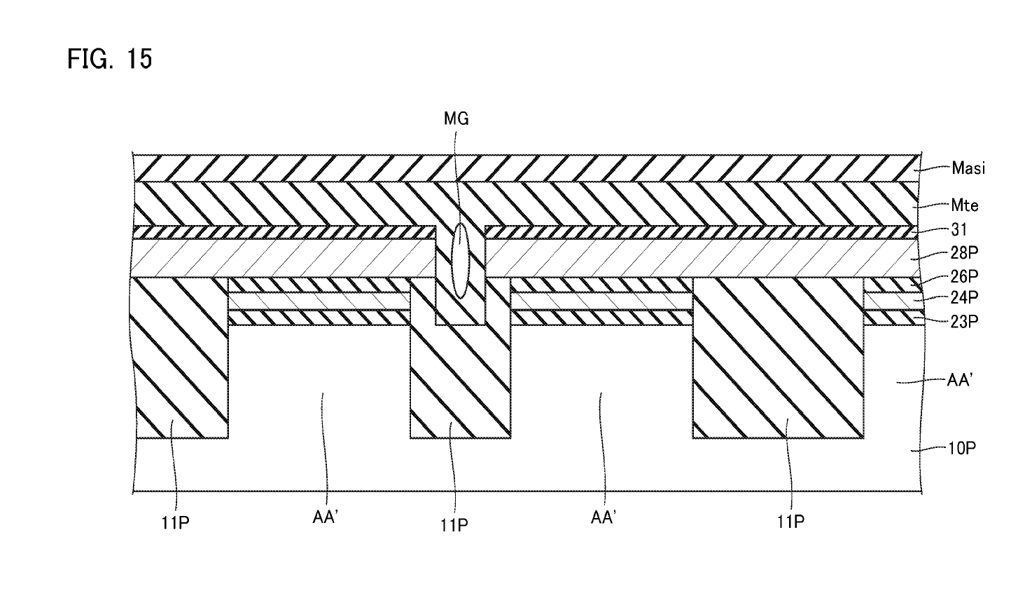

Next, as shown in FIG. 15, mask materials Mte and Masi for further patterning the gate electrode 28P in a line shape are deposited inside this element isolation trench T_{GR1} and on an upper surface of the inter-layer insulating film 31. The mask material Mte is formed by, for example, a TEOS film, and the mask material Masi is formed from, for example, amorphous silicon. The mask material Mte is implanted also inside the element isolation trench T_{GR1} and includes an air gap MG inside the element isolation trench T_{GR1}.

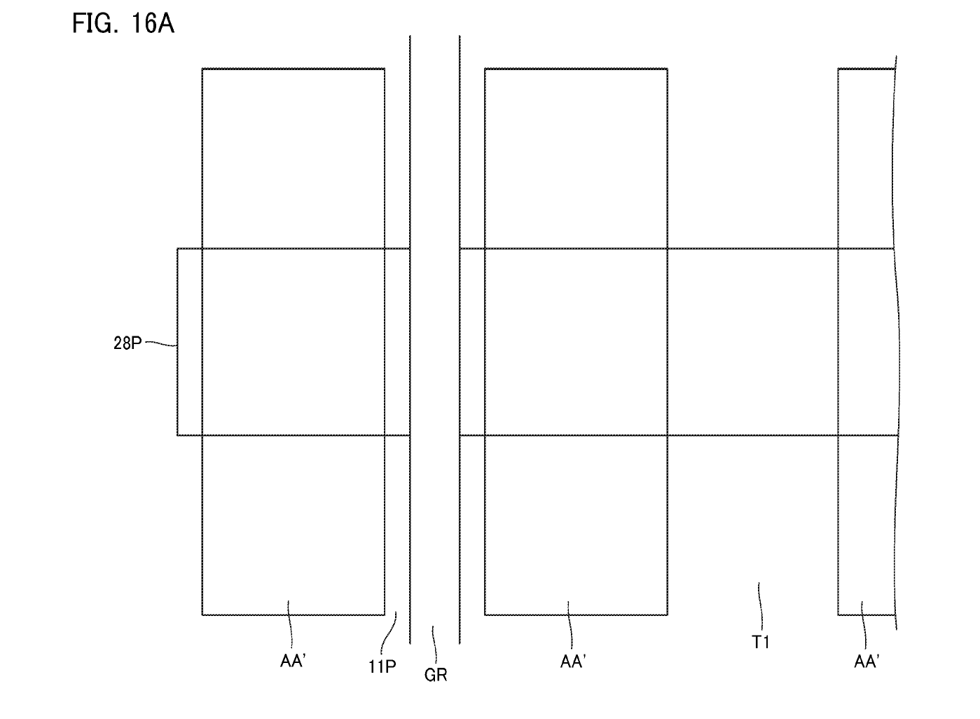

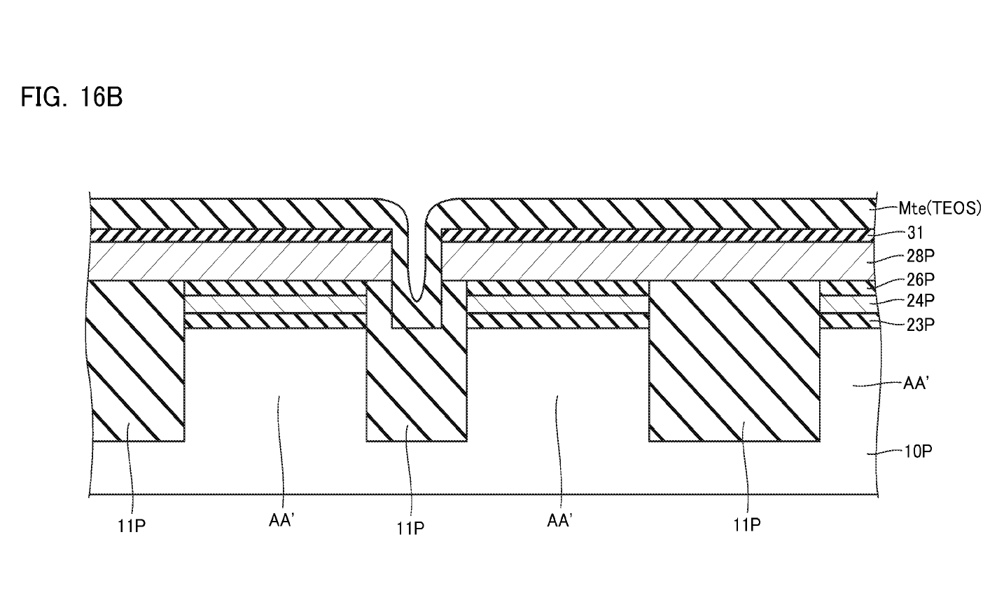

Then, as shown in FIG. 16A, these mask materials Mte and Masi are employed to pattern materials of the gate electrode 28P through floating gate 24P, in a line. As shown in FIG. 16B, by performing such patterning, the mask material Masi configured from amorphous silicon disappears, and part of the mask material Mte configured from the TEOS film remains.

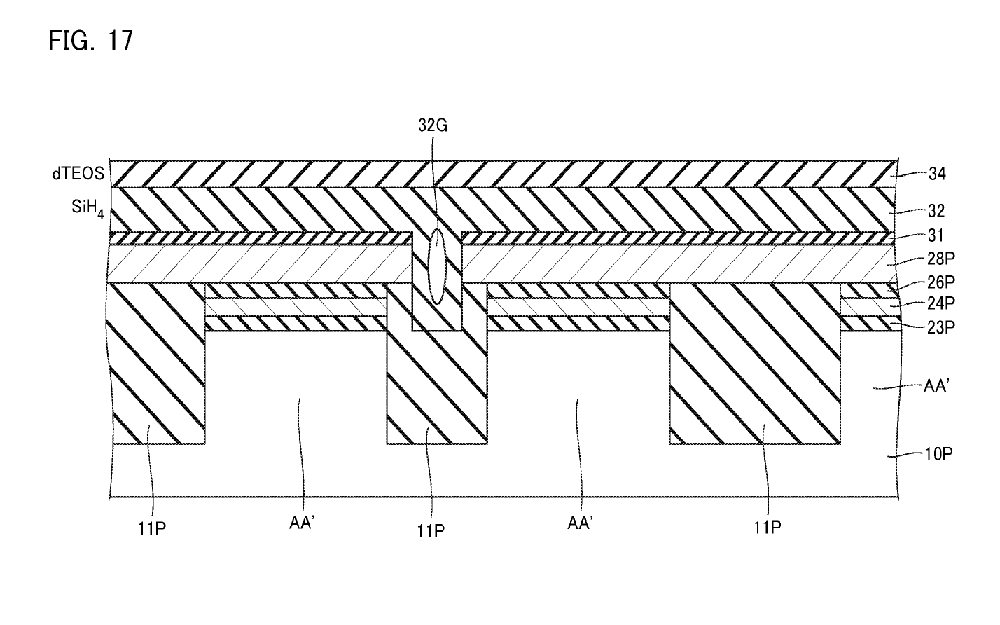

Then, as shown in FIG. 17, this mask material Mte is removed by wet etching, after which the element isolation insulating film 32 is deposited inside the element isolation trench T_{GR1} and on the upper surface of the inter-layer insulating film 31, and the inter-layer insulating film 34 is further deposited on an upper surface of the element isolation insulating film 32.

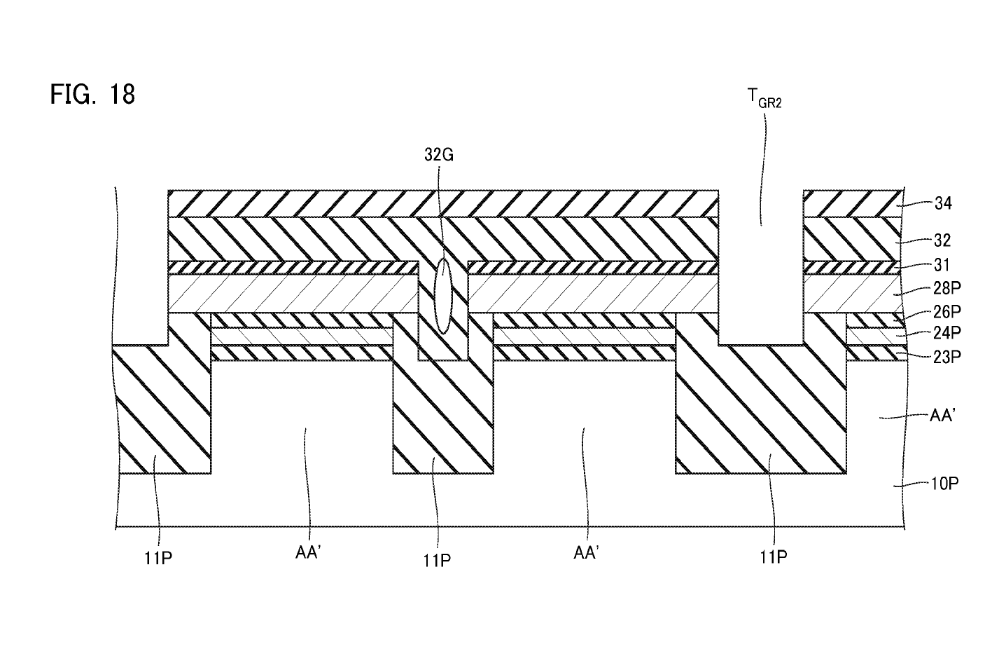

Subsequently, as shown in FIG. 18, the element isolation trench T_{GR2} of broader width than the above-mentioned element isolation trench T_{GR1} is formed above the broad-width element isolation insulating film 11P. The sidewall film SM is formed on the sidewall of this element isolation trench T_{GR2} by a well-known method, and the liner film 35, inter-layer insulating film 36, and metal wiring line M1 are further sequentially formed, whereby the structure of FIG. 9 is completed.

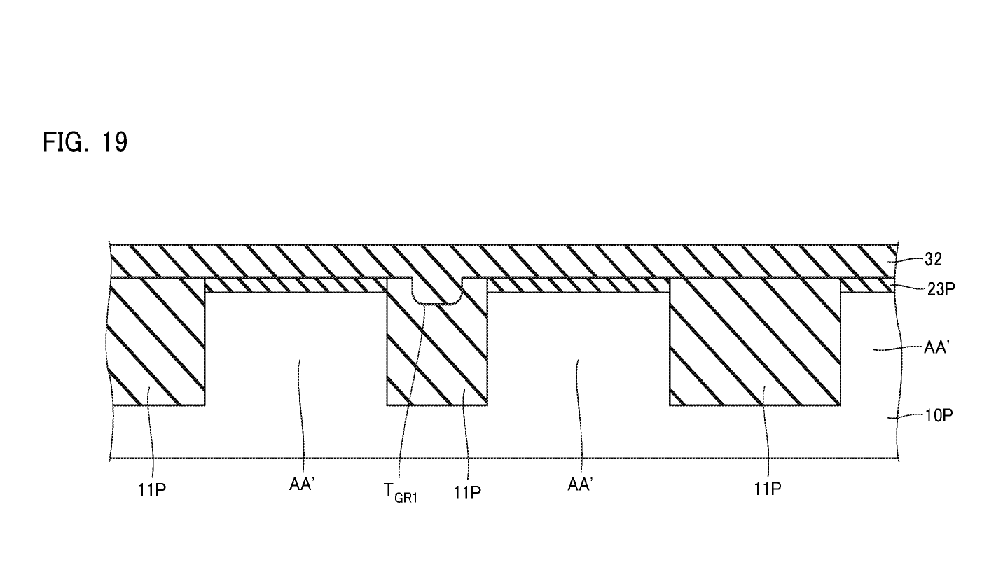

Note that as shown in FIG. 19, in a region where materials of the gate electrode 28P through floating gate 24P are removed by etching, the element isolation insulating film 11P is also etched, and a depth of the element isolation trench T_{GR1} also becomes smaller. The previously mentioned element isolation insulating film 32 is implanted inside the element isolation trench T_{GR1} also in this cross-section of FIG. 19.

As described above, due to the semiconductor device of the first embodiment, transistors formed in active areas AA′ facing each other sandwiching the narrow-width element isolation insulating film 11Pn are divided by the element isolation trench T_{GR1} formed along the longer direction of the element isolation insulating film 11Pn. By having this element isolation trench T_{GR1} implanted with the element isolation insulating film 32, the gate electrode 28P can be insulated and isolated by a narrow spacing. Therefore, a contribution can be made to miniaturization of the peripheral circuit region.

Moreover, this element isolation trench T_{GR1} can be formed simultaneously to a cutting trench when cutting a loop state wiring line formed by sidewall transfer technology, hence miniaturization of the peripheral circuit region can be achieved while also reducing the number of steps.

### Second Embodiment

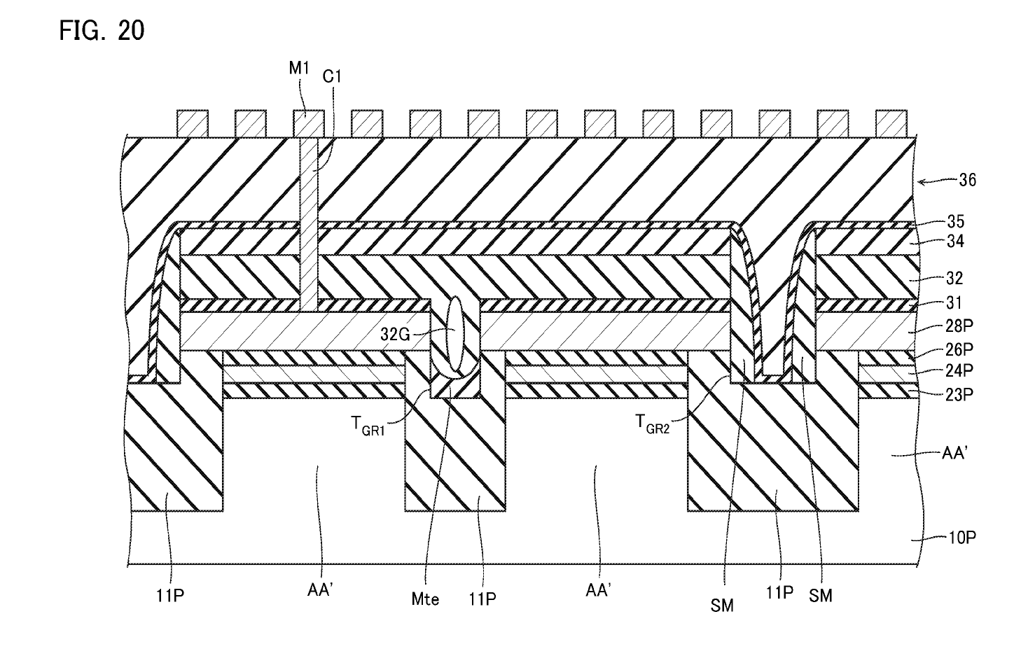

Next, a semiconductor device according to a second embodiment will be described with reference to FIG. 20. An overall configuration of the semiconductor device of this second embodiment is substantially identical to that of the first embodiment (FIGS. 1 to 8), hence a detailed description thereof will be omitted. This second embodiment has a configuration of the peripheral circuit region which differs from that of the first embodiment. This will be described with reference to FIG. 20.

FIG. 20 is a cross-sectional view taken along the line A-A′ of FIG. 8, and corresponds to FIG. 9 of the first embodiment. In FIG. 20, configuration elements identical to those of FIG. 9 are assigned with reference symbols identical to those assigned in FIG. 9, hence duplicated descriptions thereof will be omitted below.

As shown in FIG. 20, this second embodiment differs from the first embodiment in that the previously mentioned mask material Mte remains in the base of the element isolation trench T_{GR1}. In the case that the width of the element isolation trench T_{GR1} is narrow, it is conceivable that the mask material Mte on the inside of the element isolation trench T_{GR1} is not completely etched and remains. Even in this case, functioning as an element isolation insulating film can be achieved with the mask material Mte left as it is.

Similar advantages to those of the first embodiment can be displayed also by this second embodiment.

### Third Embodiment

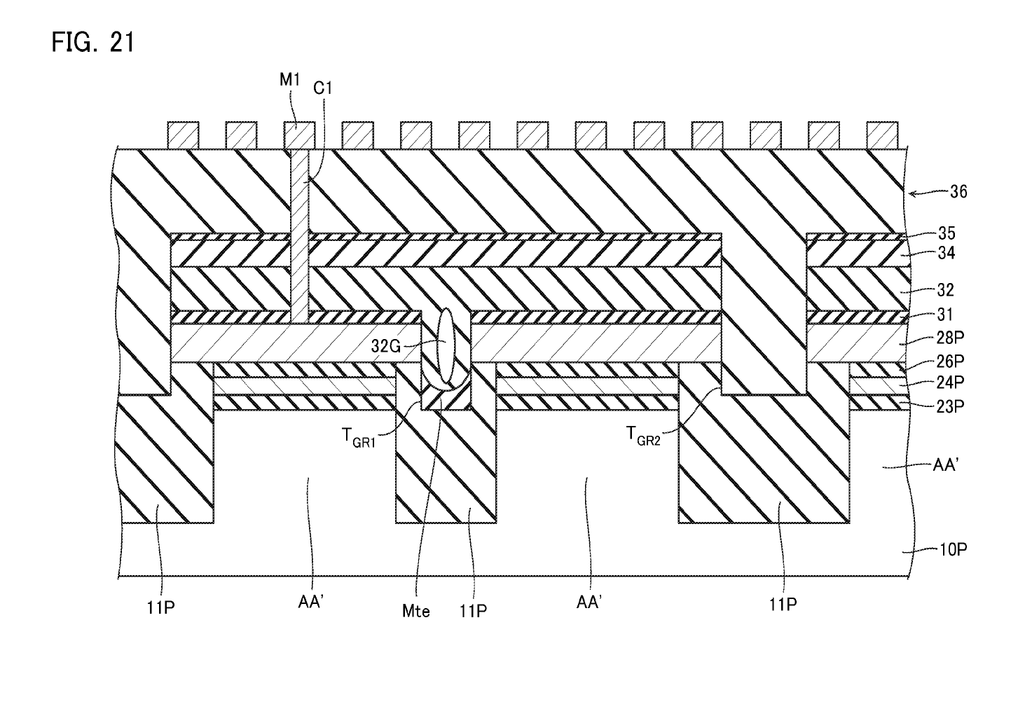

Next, a semiconductor device according to a third embodiment will be described with reference to FIG. 21. An overall configuration of the semiconductor device of this third embodiment is substantially identical to that of the first embodiment (FIGS. 1 to 8), hence a detailed description thereof will be omitted. This third embodiment has a configuration of the peripheral circuit region which differs from that of the previously mentioned embodiments. This will be described with reference to FIG. 21.

FIG. 21 is a cross-sectional view taken along the line A-A′ of FIG. 8, and corresponds to FIG. 9 of the first embodiment and FIG. 20 of the second embodiment. In FIG. 21, configuration elements identical to those of FIG. 9 are assigned with reference symbols identical to those assigned in FIG. 9, hence duplicated descriptions thereof will be omitted below.

As shown in FIG. 21, this third embodiment differs from the first embodiment in that the sidewall film SM and the liner film 35 are not formed in the element isolation trench T_{GR2} and the element isolation trench T_{GR2} is implanted by the element isolation insulating film 31. In other respects, the third embodiment is identical to the first embodiment.

### Others

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor device, comprising:
an active area where a transistor is provided;
an element isolation insulating film that insulates and isolates the active area; and
a gate electrode disposed sandwiching a gate insulating film, on the active area,
the element isolation insulating film comprising: a first element isolation insulating film having a first width; and a second element isolation insulating film having a second width larger than the first width,
the first element isolation insulating film including in an surface thereof a first element isolation trench having a third width,
the second element isolation insulating film including in an surface thereof a second element isolation trench having a fourth width larger than the third width,
the first element isolation trench having disposed therein a third element isolation insulating film, and
the second element isolation trench having disposed therein a fourth element isolation insulating film different from the third element isolation insulating film.

2. The semiconductor device according to claim 1, wherein
positions of end portions of the gate electrode facing each other via the third element isolation insulating film substantially match a position of a side surface of the first element isolation trench.

3. The semiconductor device according to claim 1, wherein
the third element isolation insulating film includes an air gap inside the first element isolation trench.

4. The semiconductor device according to claim 1, wherein
the third element isolation insulating film includes a silane film.

5. The semiconductor device according to claim 1, further comprising
a fifth element isolation insulating film different from the third element isolation insulating film, inside the first element isolation trench.

6. The semiconductor device according to claim 5, wherein
the fifth element isolation insulating film is a TEOS film.

7. The semiconductor device according to claim 5, wherein
positions of end portions of the gate electrode facing each other via the third element isolation insulating film substantially match a position of a side surface of the first element isolation trench.

8. The semiconductor device according to claim 5, wherein
the third element isolation insulating film includes an air gap inside the first element isolation trench.

9. The semiconductor device according to claim 5, wherein
the third element isolation insulating film includes a silane film.

10. The semiconductor device according to claim 1, further comprising:
a memory cell array including a memory cell;
a word line connected to the memory cell and disposed in a loop shape; and
a loop cut insulating film disposed so as to cut the loop shape,
wherein the loop cut insulating film has an identical configuration to the third element isolation insulating film.

11. The semiconductor device according to claim 1, wherein
the fourth element isolation insulating film comprises:
a sidewall film positioned on a sidewall of the second element isolation trench; and a liner film disposed on a side surface of the sidewall film.

12. A method of manufacturing a semiconductor device, comprising:
dividing a semiconductor region into a plurality of active areas by an element isolation insulating film;
forming a gate electrode material above the active area and the element isolation insulating film;
etching the element isolation insulating film and the gate electrode material above the element isolation insulating film to form a first element isolation trench; and
further implanting an element isolation insulating film in the first element isolation trench.

13. The method of manufacturing a semiconductor device according to claim 12, wherein
the semiconductor device comprises:
a memory cell array including a memory cell;
a word line connected to the memory cell and disposed in a loop shape; and
a loop cut insulating film disposed so as to cut the loop shape, and
the first element isolation trench is formed by an identical step to a second element isolation trench formed for implanting the loop cut insulating film.

14. The method of manufacturing a semiconductor device according to claim 12, wherein
the element isolation insulating film comprises: a first element isolation insulating film having a first width; and a second element isolation insulating film having a second width larger than the first width, and
the first element isolation trench is formed only in an surface of the first element isolation insulating film.

15. A semiconductor memory device, comprising:
a memory cell active area where a memory cell is provided;
a peripheral transistor active area where a peripheral transistor is formed, the peripheral transistor configuring a peripheral circuit that controls the memory cell;
an element isolation insulating film that insulates and isolates the memory cell active area and the peripheral transistor active area;
a memory insulating film, a floating gate electrode, an inter-gate insulating film, and a control gate electrode sequentially disposed on an surface of the memory cell active area; and
a gate electrode disposed sandwiching a gate insulating film, on the peripheral transistor active area,
the element isolation insulating film that insulates and isolates the peripheral transistor active area comprising: a first element isolation insulating film having a first width; and a second element isolation insulating film having a second width larger than the first width,
the first element isolation insulating film including in an surface thereof a first element isolation trench having a third width,
the second element isolation insulating film including in an surface thereof a second element isolation trench having a fourth width larger than the third width,
the first element isolation trench having disposed therein a third element isolation insulating film,
the second element isolation trench having disposed therein a fourth element isolation insulating film different from the third element isolation insulating film, and
a height of an surface of the element isolation insulating film that insulates and isolates the memory cell active area being higher than a height of an surface of the floating gate electrode.

16. The semiconductor memory device according to claim 15, wherein
positions of end portions of the gate electrode facing each other via the third element isolation insulating film substantially match a position of a side surface of the first element isolation trench.

17. The semiconductor memory device according to claim 15, further comprising:
a word line connected to the memory cell and disposed in a loop shape; and
a loop cut insulating film disposed so as to cut the loop shape,
wherein the loop cut insulating film has an identical configuration to the third element isolation insulating film.
